(19) United States
(12) Patent Application Publication
(10) Pub. No.: US 2022/0071067 A1
(43) Pub. Date: Mar. 3, 2022

(54) ELECTROMAGNETIC FIELD DISRUPTING PENDANT ASSEMBLY

(71) Applicant: Robert J. Marking, Green Acres, FL (US)

(72) Inventor: Robert J. Marking, Green Acres, FL (US)

(21) Appl. No.: 17/162,342

(22) Filed: Jan. 29, 2021

Related U.S. Application Data
(63) Continuation-in-part of application No. 29/748,114, filed on Aug. 27, 2020.

(51) Int. Cl. H05K 9/00; A44C 25/00

(52) U.S. Cl. CPC H05K 9/00; A44C 25/001

(57) ABSTRACT

An electromagnetic field disrupting pendant assembly includes a body having a front side and a back side. The body has a plurality of openings therein extending through the front and back sides. The openings consist of a first opening and a second opening spaced from each other along a first line. A third opening and a fourth opening are spaced from each other along a second line. The first and second lines are orientated perpendicular to each other. The first and third openings have a same size and the second and fourth openings have a same size. The first and third openings has a smaller size than the second and fourth openings. A first distance is defined between axes of the first and second openings and a second distance is defined between axes of the third and fourth distances. The first distance is greater than the second distance.

### CROSS-REFERENCE TO RELATED APPLICATIONS

I hereby claim the benefit under 35 U.S.C., Section 120 of U.S. application Ser. No. 29/748,114 filed Aug. 27, 2020.

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

The disclosure relates to electromagnetic field disruptive devices and more particularly pertains to a new electromagnetic field disruptive device for altering an effect electromagnetic fields (EMF) have on a person's bodily well-being.

It is well known that people are constantly subjected to EMF radiation from a variety of sources including electronic appliances, small electronics, electrical wiring within buildings, and the like. In today's digital age a person cannot avoid interaction with this type of radiation. Less understood are the effects of this radiation on a person's body. However, studies suggest that EMF radiation can alter a person's heart rate variability (HRV). HRV is the time, measured in milliseconds, between a person's heartbeat and the variation of this time. Low variation is indicative of poorer health while high variation can demonstrate an overall better condition of health. This can be explained in that a person who is healthy will have a relatively HRV which translates into that person's heart having the ability to change heart rate very quickly as required by the body. A person who is depressed, ill, stressed, or otherwise not in optimal physical condition will have a lower HRV and thus will have a heart that cannot adapt quickly to changes. Age can also alter the HRV and as a person ages their HRV will tend to decrease.

Studies have shown that when a person is subjected to EMF radiation, their HRV decreases. This is an indication not only of heart stress but of an overall decrease in body function efficiencies. That is, it can be assumed that when the heart functionality is subprime, the other organs of the body will also lose efficiency. This in turn reduces the bodies overall efficiency and energy utilization/availability. Thus fatigue, stress, injuries, and the like are all increased because of EMF exposure. The device detailed herein diminishes a person's bodily exposure from some EMF exposure to decrease the weakening effects of EMF radiation on the person's body.

### (2) Description of Related Art Including Information Disclosed Under 37 CFR 1.97 and 1.98

The prior art relates to electromagnetic field and other disruptive devices used to protect a person from harmful electromagnet radiation.

### BRIEF SUMMARY OF THE INVENTION

An embodiment of the disclosure meets the needs presented above by generally comprising a disrupting pendant assembly including a body having a front side, a back side and a perimeter edge. The body has a plurality of openings therein extending into the front side and outwardly from the back side. The openings consist of a first opening and a second opening spaced from each other along a first line. The first and second openings are each circular shaped and the first line bisects the first and second openings. A third opening and a fourth opening are spaced from each other along a second line. The first and second lines are orientated perpendicular to each other. The second line bisects the third and fourth openings. The first and third openings have a same size and the second and fourth openings have a same size. The first and third openings has a smaller size than the second and fourth openings. A first distance is defined between axes of the first and second openings and a second distance is defined between axes of the third and fourth distances. The first distance is greater than the second distance. The pendant assembly is worn by a person to alter EFM effects on the person.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a front isometric view of an electromagnetic field disrupting pendant assembly according to an embodiment of the disclosure.

FIG. 2 is a front view of an embodiment of the disclosure.

FIG. 3 is a side view of an embodiment of the disclosure.

FIG. 4 is a rear isometric view of an embodiment of the disclosure.

### DETAILED DESCRIPTION OF THE INVENTION

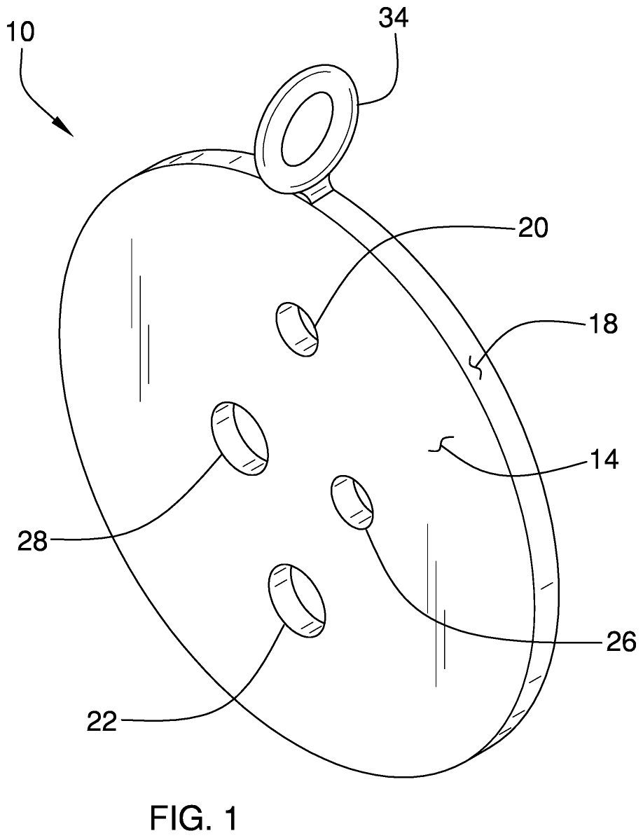

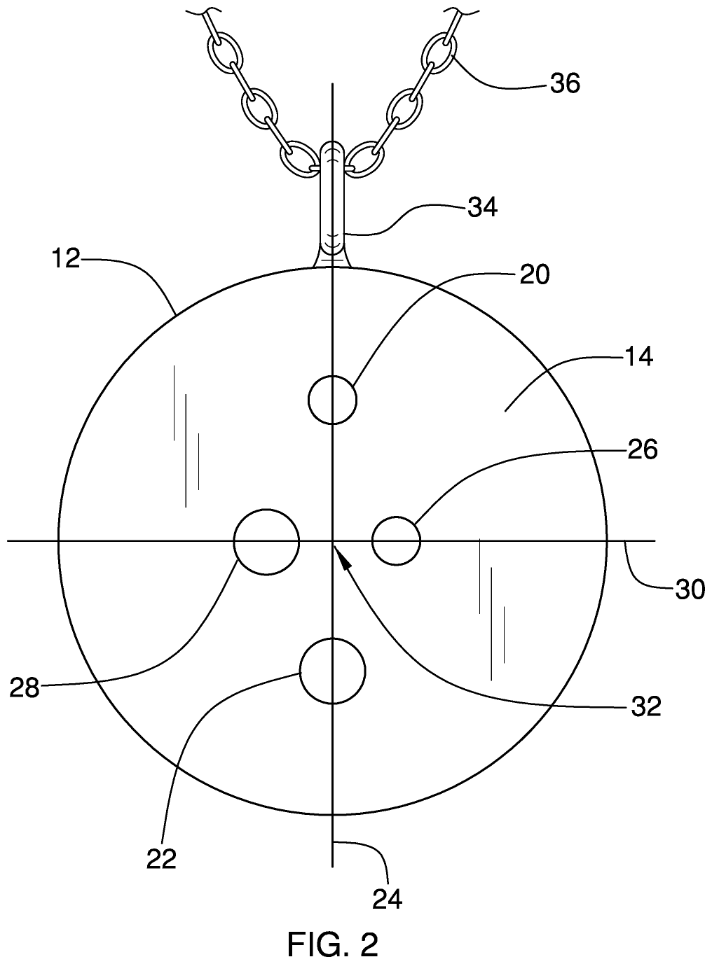

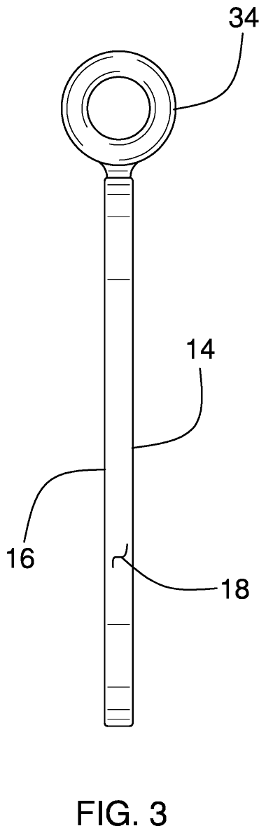

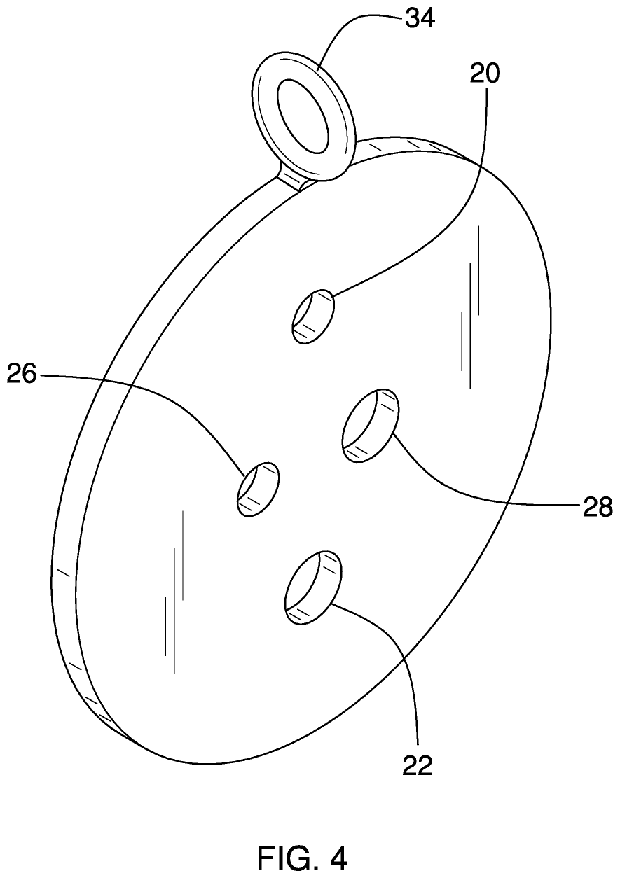

With reference now to the drawings, and in particular to FIGS. 1 through 4 thereof, a new electromagnetic field disruptive device embodying the principles and concepts of an embodiment of the disclosure and generally designated by the reference numeral 10 will be described.

As best illustrated in FIGS. 1 through 4, the electromagnetic field disrupting pendant assembly 10 generally comprises a body 12 has a front side 14, a back side 16 and a perimeter edge 18. The body 12 is typically comprised of a rigid plate that is most typically made of a metallic material. The body 12 has a plurality of openings therein extending into the front side 14 and outwardly from the back side 16. The openings consist four openings in total including a first opening 20 and a second opening 22. The first 20 and second 22 openings are spaced from each other along a first line 24. The first 20 and second 22 openings are each circular shaped. The first line 24 bisects the first 20 and second 22 openings. A third opening 26 and a fourth opening 28 are spaced from each other along a second line 30. The first 24 and second 30 lines are orientated perpendicular to each other and the second line bisects 30 the third 26 and fourth 28 openings.

An equidistant point 32 between an axis of the first opening 20 and an axis of the second opening 20 is also an equidistant point 32 between an axis of the third opening 26 and an axis of the fourth opening 28. A first distance is defined between axes of the first 20 and second 22 openings and a second distance is defined between axes of the third 26 and fourth 28 distances. A ratio of the first distance to the second distance is between 2.05:1 and 2.10:1. In one embodiment the first distance is 12.3 mm and the second distance is 5.9 mm. In another embodiment, the first distance is 9.6 mm and the second distance is 4.6 mm.

The first 20 and third 26 openings have a same size with respect to each other. The second 22 and fourth 28 openings have a same size with respect to each other. The first 20 and third 26 openings have a smaller size than the second 24 and fourth 28 openings. A ratio of the size of the first opening 20 to the second 22 opening is between 1:1.35 and 1:43. In one embodiment, the diameter of the first opening 20 is 2.10 mm and the diameter of the second opening 22 is 2.85 mm. In another embodiment, the first opening diameter 20 is 1.40 mm and the second opening 22 has a diameter of 2.00 mm. The body 12 may have any shape, though a circular shape and a diameter equal to 25.0 mm in one embodiment and 20.0 mm in another embodiment may be utilized.

The positioning of the openings 20, 22, 26 and 28 interferes with EFM radiation entering a person's body and thereby reduces the impact of the radiation on the persons HRV. In a study of the usage of the assembly 10 on a randomized set of study subjects, the HRV of 45% of test subjects was improved upon the wearing of the assembly 10. The test was conducted by subjecting the participants to an EMF source for several minutes, monitoring their HRV, and then placing one of the pendant assemblies 10 on each of the participants while continuing to monitor the HRV readings for each participant. The assemblies 10 each include a loop 34 for receiving a tether 36, such as a chain, for hanging the assembly 10 on a person's neck. Thus, in use, the pendant assembly 10 is worn by a person to alter EFM effects on the person to increase their HRV and thereby create an overall positive impact on overall bodily functions.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. A pendant assembly configured to be worn by a person to modify EMF radiation absorbed by the person, the pendant assembly comprising:
a body having a front side, a back side and a perimeter edge;
the body having a plurality of openings therein extending into the front side and outwardly from the back side, the openings consisting of:
a first opening and a second opening, the first and second openings being spaced from each other along a first line, the first and second openings each being circular shaped, the first line bisecting the first and second openings;
a third opening and a fourth opening being spaced from each other along a second line, the first and second lines being orientated perpendicular to each other, the second line bisecting the third and fourth openings;
an equidistant point between an axis of the first opening and an axis of the second opening being an equidistant point between an axis of the third opening and an axis of the fourth opening;
the first and third openings having a same size, the second and fourth openings having a same size;
the first and third openings having a smaller size than the second and fourth openings, a ratio of the size of the first opening to the second opening being between 1:1.35 and 1:43;
a first distance being defined between axes of the first and second openings, a second distance being defined between axes of the third and fourth distances, a ratio of the first distance to the second distance being between 2.05:1 and 2.10:1; and
wherein the pendant assembly is worn by a person to alter EFM effects on the person.

2. A pendant assembly configured to be worn by a person to modify EMF radiation absorbed by the person, the pendant assembly comprising:
a body having a front side, a back side and a perimeter edge;
the body having a plurality of openings therein extending into the front side and outwardly from the back side, the openings consisting of:
a first opening and a second opening, the first and second openings being spaced from each other along a first line, the first and second openings each being circular shaped, the first line bisecting the first and second openings;
a third opening and a fourth opening being spaced from each other along a second line, the first and second lines being orientated perpendicular to each other, the second line bisecting the third and fourth openings;
the first and third openings having a same size, the second and fourth openings having a same size;
the first and third openings having a smaller size than the second and fourth openings;
a first distance being defined between axes of the first and second openings, a second distance being defined between axes of the third and fourth distances, the first distance being greater than the second distance; and
wherein the pendant assembly is worn by a person to alter EFM effects on the person.
